(19) United States
(12) Patent Application Publication
(10) Pub. No.: US 2026/0147366 A1
(43) Pub. Date: May 28, 2026

(54) VOLTAGE REGULATOR WITH VARIABLE RESPONSE TIME RING OSCILLATORS

(71) Applicant: Intel Corporation, Santa Clara, CA (US)

(72) Inventors: Lior Gil, Haifa (IL); Michael Zelikson, Haifa (IL); Kosta Luria, Pardesiya (IL)

(21) Appl. No.: 18/960,801

(22) Filed: Nov. 26, 2024

(51) Int. Cl. G05F 1/575; H03K 3/03

(52) U.S. Cl. CPC G05F 1/575; H03K 3/0315

(57) ABSTRACT

Embodiments herein relate to a voltage regulator which controls an output voltage by comparing propagation speeds of signals in first and second voltage controlled oscillators (VCOs). In an example implementation, each VCO includes a chain of buffers in respective stages. One or more of the stages are evaluation stages in which the propagation speeds are compared. The comparison can include determining a stage at which the outputs of the buffers differ. Based on the comparison, an adjustment is made to a power stage, such as by turning on or off power gates of the power stage. Different weights can be associated with the different evaluation stages to affect the magnitude of the adjustment to the power stage.

### BACKGROUND

Computing devices often rely on voltage regulators to supply power to components of the devices. For example, a voltage regulator can convert the main supply voltage of a computing device, such as 12 V, down to lower voltages, such as 5 V, 3.3 V or 1.8 V. The lower voltages can be used by various components in the computing device, such as a Universal Serial Bus (USB) interface, memory such as dynamic random access memory (DRAM) and processing resources such as a central processing unit (CPU). However, various challenges are presented in designing a voltage regulator.

### BRIEF DESCRIPTION OF THE DRAWINGS

The embodiments of the disclosure will be understood more fully from the detailed description given below and from the accompanying drawings of various embodiments of the disclosure, which, however, should not be taken to limit the disclosure to the specific embodiments, but are for explanation and understanding only.

FIG. 1 depicts a digital linear voltage regulator (DLVR) 100, in accordance with various embodiments.

FIG. 2 depicts an example implementation of the VCO circuit 150 of FIG. 1, in accordance with various embodiments.

FIG. 3 depicts tables in an example implementation of the error detection and decision logic circuit 170 of FIG. 1, in accordance with various embodiments.

FIG. 4 depicts an example implementation of the register 175 of FIG. 1, in accordance with various embodiments.

FIG. 5 depicts an example implementation of the power stage 180 of FIG. 1, in accordance with various embodiments.

FIG. 6 depicts an example implementation of the buffer 211 and the amplifiers 152a and 152b of FIG. 2, in accordance with various embodiments.

FIG. 7 depicts an example implementation of the buffer 261 and the amplifiers 162a and 162b of FIG. 2, in accordance with various embodiments.

FIG. 8A depicts an example of data outputs of buffers in the first and second chains of buffers 153 and 163, respectively, of FIG. 2 in a reset state, in accordance with various embodiments.

FIG. 8B depicts an example of data outputs which follow the data outputs of FIG. 8A, where the data outputs of the buffers in the second stage (a non-evaluation stage) differ, in accordance with various embodiments.

FIG. 8C depicts an example of data outputs which follow the data outputs of FIG. 8B, where the data outputs of the buffers in the third stage (an evaluation stage) differ, in accordance with various embodiments.

FIG. 9A depicts an example of data outputs which follow the data outputs of FIG. 8A, where the data outputs of the buffers in the third and the nth stages (evaluation stages) are the same, in accordance with various embodiments.

FIG. 9B depicts an example of data outputs which follow the data outputs of FIG. 9A, where the data outputs of the buffers in the nth stage (an evaluation stage) differ, in accordance with various embodiments.

FIG. 10 depicts an example of data outputs which follow the data outputs of FIG. 8A, where the data outputs of the buffers in the nth stage (an evaluation stage) are the same, in accordance with various embodiments.

FIG. 11 depicts a flowchart of an example process for use with the DLVR 100 of FIG. 1, in accordance with various embodiments.

FIG. 12 illustrates an example of components that may be present in a computing system 1250 for implementing the techniques (e.g., operations, processes, methods, and methodologies) described herein.

### DETAILED DESCRIPTION

As mentioned at the outset, various challenges are encountered in designing a voltage regulator (VR).

Local voltage regulation is part of the power management of processors such as central processing units (CPUs) and graphics processing units (GPUs), as well as many other very-large-scale integration components. In general, there are two types of regulators: switching VRs such as a buck convertor or a switched capacitor convertor which use transformer effects, and linear VRs.

A linear VR can use an active pass device, such as a bipolar junction transistor (BJT) or a Metal Oxide Semiconductor Field-Effect Transistor (MOSFET), which is controlled by a high-gain operational amplifier. To maintain a constant output voltage, the linear regulator adjusts the pass device resistance by comparing the internal voltage reference to the sampled output voltage, and then driving the error to zero. Linear regulators are typically step-down converters. They have advantages such as being easy to design, dependable, cost-efficient, having low noise and low output voltage ripple.

A goal of local voltage regulation is to ensure accurate voltage positioning, in accordance with a pre-defined target/work point voltage and, ideally, keep this voltage independent of load changes, e.g., rate of change of current (dI/dt), or input voltage variations over time (dV/dt). This task is challenging when a regulated domain operates at high frequencies (e.g., GHz range) and high currents (e.g., tens of Amperes).

To achieve the required quality of the load and line regulations, the control loop of a regulator should have a fast response, preferably faster or of the order of the characteristic time constants of the excitations. In a modern CPU, with operational frequencies reaching 6 GHz and above, it means that the loop delay should be of order of few nanoseconds (ns), for instance.

Another important figure of merit of an integrated voltage regulator is its quiescent losses—the lower, the better. With a large number of integrated regulators in a die, even quiescent losses of order of 10 mW, may sum up to more than 100 mW on a die level—which is very significant for a CPU power budget.

Some solutions feature either an attempt to design for a short loop delay, or to introduce non-linear control (NLC) of the response to significant (i.e., exceeding a predefined threshold) changes in output current (Iout), output voltage (Vout), or input voltage (Vin).

Specifically, a first approach is a truly linear control mode, where the state of a regulator power stage is always governed by a linear controller. An implementation of the controller and of the power stage (PS) can be analog, digital, or mixed mode. A second approach is a combination of a linear control mode and a non-linear controller. An alternative approach is to combine linear control with a non-linear reaction to certain transient excitations.

However, these solutions have a number of disadvantages. For example, with analog implementations, the speed of the change in the PS conductivity is limited by the driving capabilities of the controller. The higher the required speed, the larger should be the controller driver and, hence, the higher the associated power dissipation. Also, the cost of the area that is used by an analog circuitry becomes very high.

Additionally, to achieve high bandwidth when using a Digital Linear Voltage Regulator (DLVR)-based power architecture, a high-speed clock is employed, e.g., having a frequency in the multi-GHz region. This results in high power dissipation and introduces integration challenges.

To avoid a high speed clock, and still enable a fast response to transient excitations, a slower (with respect to the fully linear approach) linear loop and a non-linear control can be used. The NLC provides a very fast (e.g., 1-2 ns) response to a load transient, when the excitation exceeds a certain threshold or thresholds. The main drawback of this approach is that when the NLC activates, it disconnects the linear control. Consequently, the transition back to the linear control regime is very challenging and requires special attention. Even though, since the conditions that lead to NLC “firing” are not deterministic, a series of NLC invocations (NLC chattering) frequently occur which may lead to unpredictable and substantial power loss. Finally, the NLC approach, due its unpredictability, increases the testing complexity—to avoid a risk of insufficient coverage.

The solutions provided herein address the above and other issues. In one aspect, the solutions provide a Digital Integrated Voltage Regulator (DIVR) that enables a very short (e.g., about 1 ns) adaptive loop delay without increasing the quiescent power of the regulator. The proposed solutions do not require a fast (e.g., 1-2 GHz range) external clock. In addition, the solutions allow for simpler high volume manufacturing testing procedures and hence, a reduced test time and cost.

In one aspect, the solutions provide a VR circuit having two voltage control oscillators (VCOs), also referred to as ring oscillators, arranged in parallel. A first, variable-delay VCO receives an input error, ε(t)=Vsense (sensed voltage of load)−Vwp (work point or target voltage). A second, fixed delay, VCO serves as a reference. Each VCO includes an equal number of buffers arranged in a chain in respective stages, and each buffer provides a 0 or 1 voltage output based on its inputs. For example, the first VCO includes a first chain of a number n buffers and the second VCO includes a second chain of n buffers. In an example implementation, each buffer includes a pair of inverters and a variable resistor in each inverter. The variable resistor receives a control gate voltage which is based on the input error, to control its resistance.

Depending on the ε(t) polarity, the variable-delay VCO may be slower or faster than the fixed-delay VCO at one or more of the stages by a time delta dt=f[ε(t)] per stage. This delay difference is accumulated along the stages of the oscillators, until one of the buffers outputs a “1”, while the other buffer in the same stage has an output which is still at its reset value (“0”). Once this state is reached, the compensator changes the effective resistance of an associated power stage accordingly. The larger the error, the faster the response of the compensator. A relatively large error is associated with the outputs of the variable-delay VCO and fixed-delay VCO differing at a relatively early stage. Therefore, this approach is referred to as a Variable Response Time Control-based VR. In an example implementation, the VR is an integrated voltage regulator (IVR), e.g., a VR that is contained within a single integrated circuit (IC) package or chip.

The VCOs may be evaluated at one or more selected evaluation stages. Each stage can be an evaluation stage for the highest control granularity, or just a subset of the stages can be evaluation stages. Different weights may be associated with the different stages to determine an appropriate adjustment of the power stage. The adjustment can involve turning on or off one or more power gates among a set of power gates, for instance.

The solutions provide a number of advantages, including enabling a self-timed voltage regulation with a response time that is proportional to the magnitude of the voltage error. In such a way, a significant quiescent power reduction is achieved. The same control algorithm can be used across the whole range of ε(t), and the behavior of the regulator is fully deterministic. The system is self-timed and does not require external clock. The design is based on a comparison of two identical oscillators (e.g., identical other than due to averaged within-die variations) and its sensitivity to systematic variations is low. Hence, the proposed design approach is less process dependent, requires simpler testing and features a reduced area.

These and other features will be further apparent in view of the following discussion.

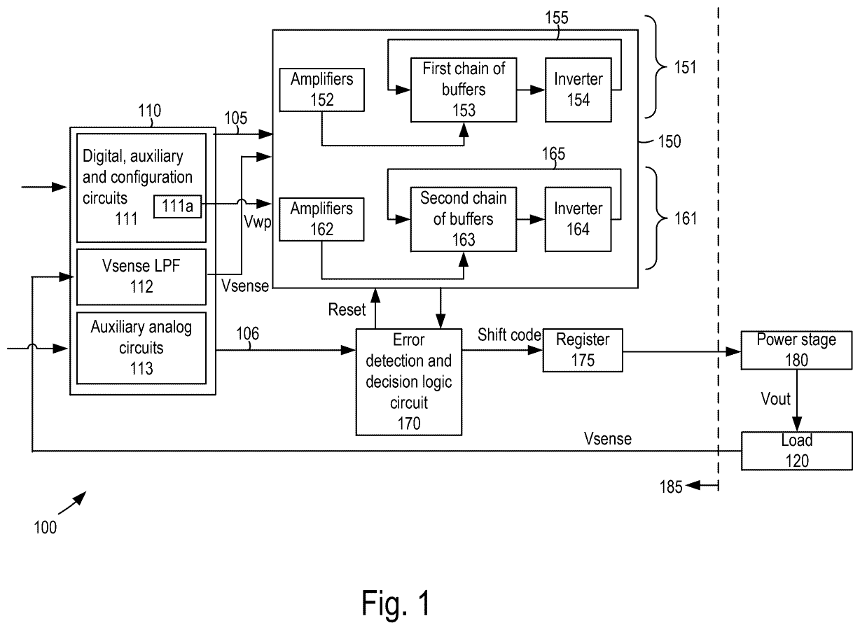

FIG. 1 depicts a digital linear voltage regulator (DLVR) 100, in accordance with various embodiments. The DLVR performs a number of functions including comparing the actual output voltage at a time point t, Vsense(t), to the desired work point voltage, Vwp, and calculating the required compensator output based on the current value of the input error, ε(t)=Vsense(t)−Vwp, and in some cases historic values such as a previous error and a previous compensator output. If a change in the output or input voltages exceeds predefined thresholds, a non-linear action may be taken to adjust the effective resistance of the power stage in accordance with the calculated compensator output value.

In a comparative approach, an update of a compensator output occurs synchronously with a clock, regardless of the amplitude of the error signal. Hence, to adequately respond to very steep load transients (e.g., tens of A/ns), the DLVR clock frequency must be in the GHz range. However, for most of the lifetime of the product in which the DLVR is provided, the load current time variations are much smaller than its extreme value, and for a typical operational regime, a substantially slower response could be sufficient. Non-linear control partially addresses this, but includes undesired features such as unpredictability and potential chattering.

The DLVR 100 of FIG. 1 addressed the above issues. The main part of the compensator can include two identical VCOs with respective chains of buffers. The bias input of the first VCO 151 is fed by an amplified error signal, and the second VCO 161 serves as the reference branch, representing an ideal regulation case, i.e., Vsense(t)=Vwp.

Once a condition is reached indicating that a propagation speed of signals in the VCOs differs, a response to the current error is calculated in the decision logic circuit 170, e.g., circuitry. Its output can be a shift code, which can be either [−1, 0, 1], or can be dependent on the error magnitude.

The status of the power stage 180 is determined by an n-bit control register 175. The shift code SC(i), calculated above, is added to the previous state of the control register, CR(i−1) to provide a new state as follows: CR(i)=CR(i−1)+SC(i). The power stage is then updated based on the new state of the resister.

The VR includes a VCO circuit 150 which compares a propagation speed of a signal in a variable-delay VCO 151 to a propagation speed of a signal in a reference VCO 161. The variable-delay VCO 151 includes a first chain of buffers 153 (a variable-delay chain of buffers) followed by an inverter 154, where an output of the inverter is fed back to the chain on a first feedback path 155. Additionally, outputs of amplifiers 152, e.g., one or more amplifiers, are coupled to variable-resistance elements within the buffers. The outputs of the amplifiers 152 are based on a difference between a work point voltage and a sensed voltage of a load 120.

Similarly, the reference VCO 161 includes a second chain of buffers 163 (a fixed-delay or reference chain of buffers) followed by an inverter 164, where an output of the inverter is fed back to the chain on a second feedback path 165. Outputs of amplifiers 162, e.g., one or more amplifiers, are coupled to fixed-resistance elements within the buffers. The output of the amplifiers 162 are nominally equal to a bias voltage of the amplifiers, as the inputs of the amplifiers receive the same voltage, e.g., the work point voltage. The details of the implementation of the circuit 150 may vary, while keeping the main idea of comparing the response of the error-dependent chain 151 to the reference chain 161. Amplifiers 152 and 162 may, or may not be present, depending on the strength of the error signal and the required sensitivity of the VR.

The VCO circuit 150 provides data to an error detection and decision logic circuit 170 indicating whether the propagation speed of the signals is different between the two VCO at any of one or more evaluation stages of the VCOs. In response to the data, the circuit 170 can provide a shift code to a register 175. The register can include storage elements such as flip flops which control the resistance of a power stage 180. For example, the data of the register can control which power gates are turned on among a set of power gates of the power stage. For example, if the data indicates that the propagation speed is faster in the variable-delay VCO 151 than in the reference VCO 161, the shift code can reduce the number of turned on power gates. In one approach, the propagation speed is faster in the variable-delay VCO 151 than in the reference VCO 161 when Vsense>Vwp, and reducing the number of turned on power gates reduces Vsense. Similarly, the propagation speed is slower in the variable-delay VCO 151 than in the reference VCO 161 when Vsense<Vwp, in which case increasing the number of turned on power gates increases Vsense.

If the data indicates the propagation speeds are essentially the same, there is no adjustment to the power stage.

When an adjustment is made, the magnitude of the adjustment can be based on the magnitude of the propagation speed difference. When the speed difference is detected at multiple evaluation stages of the VCOs, a speed difference that is detected in a relatively early stage of the VCOs indicates a relatively large adjustment should be made. An adjustment of the power stage can thus be based on a closeness of the first stage to input ends of the first and second chains of buffers.

The circuit 170 can also provide a reset signal to the VCOs to reset the buffer outputs to 0, for example.

The power stage 180 provides power/current at a voltage Vout to a load 120, such as a processor, logic block or other circuit. Vsense, the sensed voltage of the load, is detected at a low pass filter (LPF) 112 in a set of circuits 110. The set of circuits 110 further includes digital, auxiliary and configuration circuits 111 (including a voltage source 111a) and auxiliary analog circuits 113. The digital, auxiliary and configuration circuits 111 can further include, e.g., fuses, biases for high-voltage protection, and debug/characterization circuitry. The set of circuits 110 provides outputs include Vsense and Vwp to the amplifiers 152 and 162 of the VCO circuit 150. The set of circuits 110 can also provide control signals on a path 106 to the error detection and decision logic circuit 170, and control signals on a path 105 to the VCO circuit 150.

The circuits 110, 150, 170 and 175 can together form a compensator 185.

Example implementation details of the DLVR 100 are discussed below.

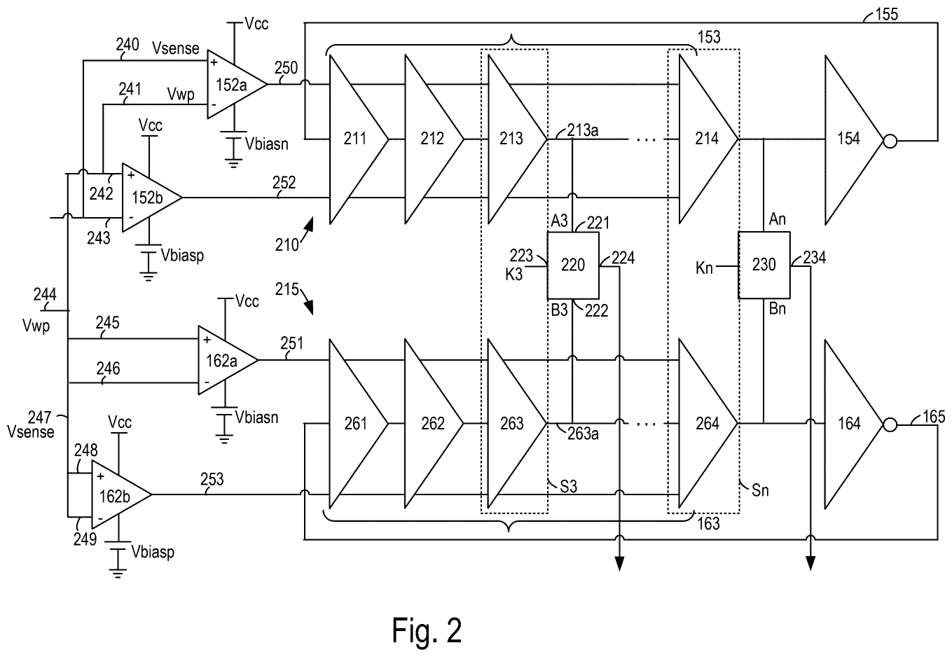

FIG. 2 depicts an example implementation of the VCO circuit 150 of FIG. 1, in accordance with various embodiments. The circuit depicts the first and second chains of buffers 153 and 163, respectively. The first chain includes buffers 211, 212, 213, . . . , 214 and the second chain includes buffers 261, 262, 263, . . . , 264. The buffers 214 and 264 are the last or nth buffers in their respective chains, where n is the number of stages/buffers in the chains. Generally, n can be at least 2, or at least 5-10 or more. In an example implementation, n=96 stages. In this example, the third and nth stages are the evaluation stages.

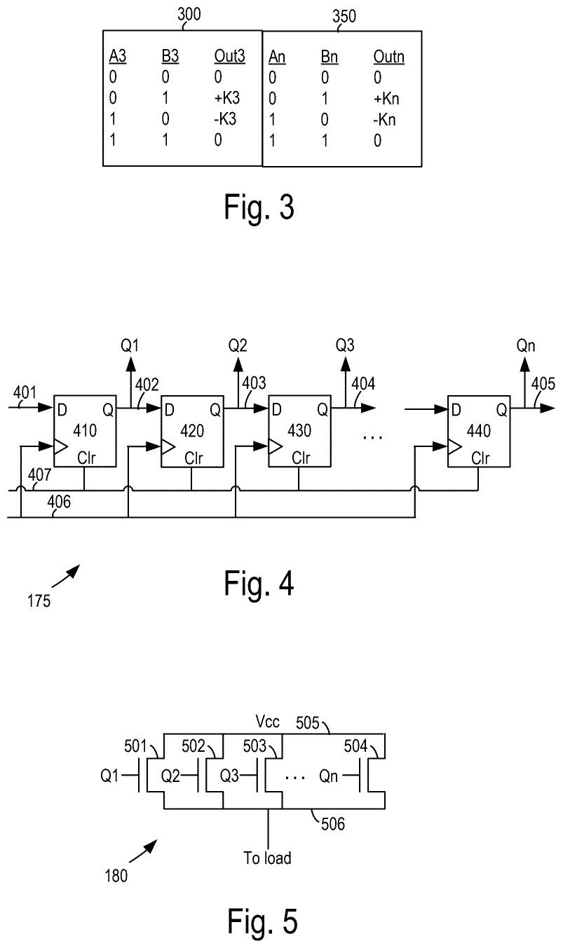

In each evaluation stage, a comparison circuit receives output data of the buffers of the stage from the first and second chains, and provides its own output to the error detection and decision logic circuit 170. This output can be weighted by a weight associated with the comparison circuit or stage. For example, in the third stage S3, a comparison circuit 220 includes inputs 221, 222 and 323, and an output 224. The input 221 (A3) is coupled to the output node 213a of the buffer 213, and the input 222 (B3) is coupled to the output node 263a of the buffer 263. The input 223 receives a weight K3 which influences a magnitude of the output on the output node 224, in one possible implementation. In another possible implementation, the weight is applied instead at the error detection and decision logic circuit 170 (see FIG. 3). The comparison circuit 220 can set a −1, 0 or 1 value, for example. −1 can be set if data 1 is on the output node 263 a and data 0 is on the output node 213a. A 1 can be set if data 1 is on the output node 213a and data 0 is on the output node 263a. A 0 can be set if both output nodes 213a and 263a have the same data output. The comparison circuit 220 provides an output to the error detection and decision logic circuit 170.

Similarly, in the nth and last stage Sn, a comparison circuit 230 provides an output on an output node 234 based on outputs of the buffers 214 and 264 (An and Bn, respectively) and a weight Kn. As mentioned, a relatively large weight can be associated with stages that are relatively close to the input ends 210 and 215 of the chains 153 and 163, respectively, so that K3>Kn. That is, the weights can be a decreasing function of a number of stages between the input end of the chain and the evaluation stage. This feature is supported by an observation that the larger the input error, the earlier (closer to the input stage) a difference between the measurement and the reference chain buffers outputs would appear.

This example includes two evaluation stages, but generally one or more can be used, depending on the level of granularity which is desired for regulating the output voltage of the VR. A larger number of evaluation stages will result in a finer granularity. Typically the evaluation stages can include the last or nth stage.

The amplifiers 152 of FIG. 1 include first and second amplifiers 152a and 152b, respectively, and the amplifiers 162 of FIG. 1 includes first and second amplifiers 162a and 162b, respectively. The amplifiers 152a and 162a have a first power supply node at Vcc and a second power supply node at Vbiasn<Vcc. The amplifiers 152b and 162b have a first power supply node at Vcc and a second power supply node at Vbiasp<Vcc. In one approach, Vbiasn and Vbiasp>0 V. Additionally, Vbiasn and Vbiasp can be equal or different.

The amplifiers can be differential amplifiers which amplify the difference between the two input voltages while suppressing any voltage common to the two inputs. The output is ideally proportional to the difference between the inputs multiplied by the gain (G) of the amplifier, shifted by a dedicated bias voltage to ensure an optimal direct current operation point for the downstream buffers.

For example, the output of amplifier 152a is V=Vbiasn+G*(Vsense-Vwp), and the output of amplifier 152b is V=Vbiasp+G*(Vwp-Vsense)=Vbiasp−G*(Vsense-Vwp). The amplifier 152a receives Vsense and Vwp on non-inverting and inverting input nodes 240 and 241, respectively, and provides its output on an output node 250. The amplifier 152b receives Vwp and Vsense on non-inverting and inverting input nodes 242 and 243, respectively, and provides its output on an output node 252. The output of the amplifiers 152a and 152b is thus based on the difference between Vsense and Vwp. The inputs are thus reversed for the amplifier 152b compared to the amplifier 152a. The amplifiers 152a and 152b can be identical.

In contrast, the amplifier 162a receives Vwp on both the non-inverting and inverting input nodes 245 and 246 and provides its output on an output node 251, and the amplifier 162b also receives Vwp on both its non-inverting and inverting input nodes 248 and 249, respectively, and provides its output on an output node 253. The amplifiers 162a and 162b thus have their respective inputs coupled to a common voltage node 244 which can be at Vwp or another voltage. The output of the amplifier 162a on the output node 251 is Vbiasn and the output of the amplifier 162b on the output node 253 is Vbiasp. The amplifiers 162a and 162b can be identical. The amplifiers 162a and 152a, and 162b and 152b are meant to be identical to cancel out design imperfections, in an example implementation.

The voltage on the output nodes 250 and 252 is coupled to each of the buffers in the first chain of buffers 153, and the voltage on the output nodes 251 and 253 is coupled to each of the buffers in the second chain of buffers 163, in one approach.

The bias voltage of the second chain of buffers is zero since both inputs of amplifiers 162a and 162b are identical. Each buffer of the second chain of buffers has a delay Teff(0). In contrast, the bias voltage of the first chain of buffers depends on the difference between the sensed voltage and the work point voltage, i.e., on ε(t). This delay is denoted by Teff(ε(t)), and the difference between the two delays is denoted by dTeff(ε(t))=Teff(e(t))−Teff(0). This delay is accumulated along the chains, and after k stages, the difference between the total delays is dT_{S}(ε(t))=k* dTeff(ε(t)).

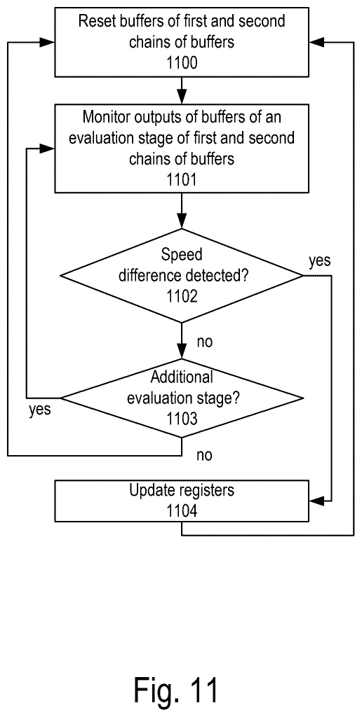

For example, assume that at an initial condition, all buffers are reset to 0 and the inputs of the first stage are “1,” e.g., due to the inversion of the 0 to 1 by the inverters. These “1” start propagating through both chains but at different speeds. After an N^{th} stage, where N>dT_{S}(ε(t))/dTeff(ε(t)), the N^{th} output of the faster chain will equal “1”, while the output of the other chain is still “0”. This event is detected, and the compensator output is updated, factoring in that the lower the number N, the larger e(t) and hence the stronger response can be tolerated (through weights K in FIG. 3). Simultaneously with sending the shift code to the shift register, the two chains can be reset to the initial condition, and the process continues from the beginning. See also FIG. 11.

FIG. 3 depicts tables in an example implementation of the error detection and decision logic circuit 170 of FIG. 1, in accordance with various embodiments. The circuit can implement tables 300 and 350. Each table cross-references the buffer outputs to an output for adjusting the power stage according to a weight of the stage. For example, the table 300 is for the third stage and cross-references A3 (the output of buffer 213) and B3 (the output of buffer 263) to an output Out3. A3=0 and B3=0 are cross-referenced to Out3=0, A3=0 and B3=1 are cross-referenced to Out3=+K3, A3=1 and B3=0 are cross-referenced to Out3=−K3, and A3=1 and B3=1 are cross-referenced to 0.

The table 350 is for the nth stage and cross-references An (the output of buffer 214) and Bn (the output of buffer 264) to an output Outn. An=0 and Bn=0 are cross-referenced to Outn=0, An=0 and Bn=1 are cross-referenced to Out3=+Kn, An=1 and Bn=0 are cross-referenced to Outn=−Kn, and An=1 and Bn=1 are cross-referenced to 0.

FIG. 4 depicts an example implementation of the register 175 of FIG. 1, in accordance with various embodiments. The register includes a number n of D-type flip-flops 410, 420, 430, . . . 440, in this example implementations. Other implementations are possible as well. The register takes in serial data, e.g., from the circuit 170, on a path 401 at the data input D of the flip-flop 410 and provides parallel data at the outputs (Q) 402, 403, 404, . . . , 405 of each flip-flop in response to a clock pulse on a path 406. A clear (Clr) or reset signal can be provided to each flip-flop on a path 407. The data at the outputs 402, 403, 404, . . . , 405 is represented by Q1, Q2, Q3, . . . , Q4, respectively. This data can represent respective turn on or turn off voltages for respective power gates, for example. The outputs can be coupled to control gates of the power gates/transistors, in one possible approach.

FIG. 5 depicts an example implementation of the power stage 180 of FIG. 1, in accordance with various embodiments. The power stage can include power gates 501, 502, 503, . . . , 504 such as n-type MOSFETs, which are coupled at one side to a power supply node 505 at Vcc and at an opposite side to a power rail 506 which in turn is coupled to a load. The control gates of the transistors are biased based on the data in the register. For example, the control gates of the transistors are biased based on the data Q1, Q2, Q3, . . . , Q4.

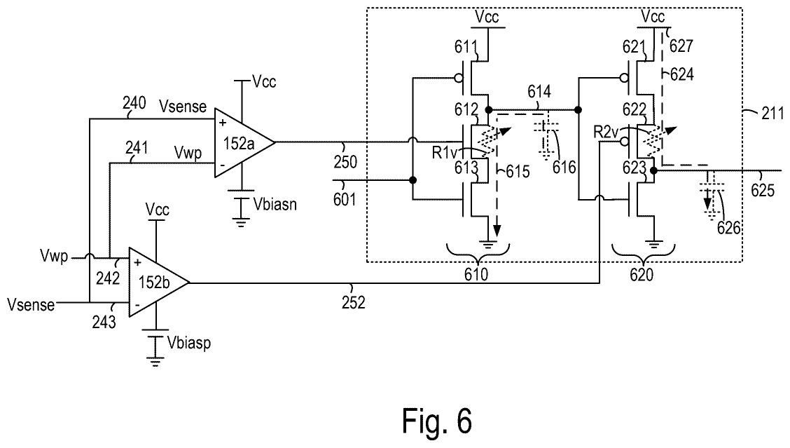

FIG. 6 depicts an example implementation of the buffer 211 and the amplifiers 152a and 152b of FIG. 2, in accordance with various embodiments. Each of the buffers in the first chain of buffers can be configured similarly and coupled to the amplifiers 152a and 152b as indicated. The buffer has an input node 601 coupled to the feedback path 155 and an output node 625. The buffer includes first and second inverters 610 and 620, respectively, coupled between a power supply node at Vcc and ground. The input node 601 of the buffer is also the input node of the first inverter 610, and the output node 614 of the first inverter is also the input node of the second inverter. The output node 625 of the buffer is also the output node of the second inverter.

The inverter 610 includes, in series, a p-type transistor 611, an n-type transistor 612, and an n-type transistor 613. The transistors can be MOSFETs, for example. The transistors 611 and 613 have their control gates coupled at the input node 601 of the inverter 610 and buffer 211. The output node 614 of the inverter 610 is coupled to the control gates of transistors 621 and 623 in the inverter 620.

In the inverter 610, the transistor 611, when turned on (conductive), can pull up the voltage of the node 614 to Vcc, and the transistor 613, when turned on, can pull down the voltage of the node 614 to ground. Similarly, in the inverter 620, the transistors 621 and 623 are pull up and pull down transistors, respectively. The inverter 620 includes, in series, a p-type transistor 621, an n-type transistor 622, and an n-type transistor 623.

The first and second variable resistors may thus comprise respective transistors, where a first variable resistor 612 has an opposite polarity, e.g., n-type, than the second variable resistor 622, e.g., p-type.

The transistor 612 acts as a variable resistor R1v in the inverter 610 with a resistance that is a function of its control gate voltage on the output node 250 of the amplifier 152a. As an n-type MOSFET 612, R1v is lower when its control gate voltage is higher, and a larger current 615 can flow from a virtual capacitor 616 through the output node 614, R1v, and the transistor 613 to ground. The voltage on the output node 250 is higher when Vsense is higher.

Similarly, the transistor 622 acts as a variable resistor R2v in the inverter 620 with a resistance that is a function of its control gate voltage on the output node 252 of the amplifier 152b. As a p-type MOSFET 622, R2v is lower when its control gate voltage is lower, and a larger current 624 can flow from the power supply node 627 through the transistor 621, R2 v, the output node 625 and a virtual capacitor 626 to ground. The voltage on the output node 252 is lower when Vsense is higher.

The buffers can initially be reset by the circuit 170 to have a 0 output. The 0 output is propagated through the chain of buffers to the associated inverter, and an output of the inverter, e.g., a 1, is fed back to the input of the chain of buffers. The 1 is then propagated through the chain of buffers.

The propagation speed of a signal as it passes through the buffers of the first chain of buffers will be variable as a function of the difference between Vsense and Vwp. When Vsense is relatively high, e.g., higher than Vwp, the propagation speed will be relatively higher, and when Vsense is relatively low, e.g., lower than Vwp, the propagation speed will be relatively lower. In contrast, the propagation speed of the signal as it passes through the buffers of the second chain of buffers will be essentially fixed and independent of the difference between Vsense and Vwp. The outputs of the buffers in the first and second chain of buffers can therefore differ at a given stage, and this difference can be detected by the comparison circuits 220 and 230, for example (FIG. 2).

The resistors R1v and R2v are voltage-dependent resistors inserted in the discharging path of the first inverter and in the charging path of the second inverter. The voltage-dependent resistance value is linearly proportional to the magnitude of the applied voltage. Hence, the total propagational delay time of a buffer, T, varies linearly with abs(Vsense-Vwp). This assumes the transistors that serve as variable resistors are biased in the triode region and that the second order term of their current-voltage (I/V) curve is neglected. The delay of the current path 615 is R1v×C1 (the capacitance of the virtual capacitor 616), and the delay of the current path 624 is R2v×C2 (the capacitance of the virtual capacitor 626).

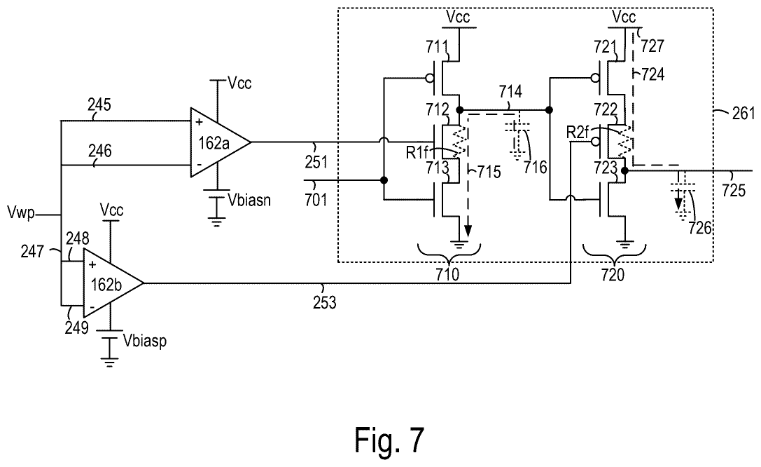

FIG. 7 depicts an example implementation of the buffer 261 and the amplifiers 162a and 162b of FIG. 2, in accordance with various embodiments. Each of the buffers in the first chain of buffers can be configured similarly and coupled to the amplifiers 162a and 162b as indicated. The buffer has an input node 701 coupled to the feedback path 165 and an output node 725. The buffer includes first and second inverters 710 and 720, respectively, coupled between a power supply node at Vcc and ground. The input node 701 of the buffer is also the input node of the first inverter 710, and the output node 714 of the first inverter is also the input node of the second inverter. The output node 725 of the buffer is also the output node of the second inverter.

The inverter 710 includes, in series, a p-type transistor 711, an n-type transistor 712, and an n-type transistor 713. The transistors can be MOSFETs, for example. The transistors 711 and 713 have their control gates coupled at the input node 701 of the inverter 710 and buffer 261. The output node 714 of the inverter 710 is coupled to the control gates of transistors 721 and 723 in the inverter 720.

In the inverter 710, the transistor 711, when turned on, can pull up the voltage of the node 714 to Vcc, and the transistor 713, when turned on, can pull down the voltage of the node 714 to ground. Similarly, in the inverter 720, the transistors 721 and 723 are pull up and pull down transistors, respectively. The inverter 720 includes, in series, a p-type transistor 721, an n-type transistor 722, and an n-type transistor 723.

The transistor 712 acts as a fixed resistor R1f in the inverter 710, and the transistor 722 acts as a fixed resistor R2f in the inverter 720. A current 715 can flow from a virtual capacitor 716 through the output node 714, R1f, and the transistor 713 to ground. A current 724 can flow from the power supply node 727 through the transistor 721, R2f, the output node 725 and a virtual capacitor 726 to ground.

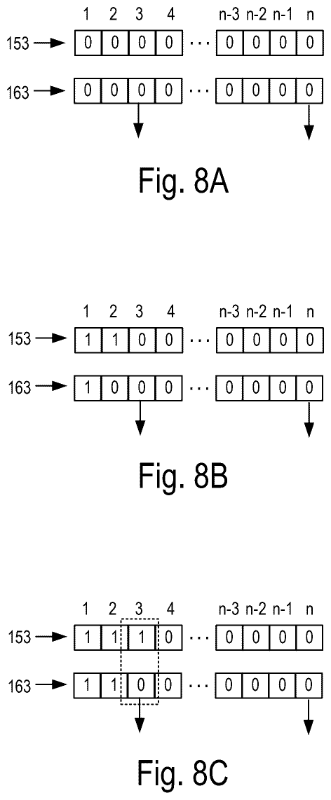

FIG. 8A depicts an example of data outputs of buffers in the first and second chains of buffers 153 and 163, respectively, of FIG. 2 in a reset state, in accordance with various embodiments. The buffers are in a number n stages 1, 2, 3, 4, . . . , n-3, n-2, n-1 and n. The output of each buffer in the chains 153 and 163 is a 0 in this state, so that no adjustment in the power stage is indicated. As mentioned, the circuit 170 can provide the buffers of the first and second chains in a reset state in which a 0 is output from each buffer. The vertical arrows denote the evaluation stages which are the third and nth stages, consistent with FIG. 2. The other stages are non-evaluation stages in this example.

FIG. 8B depicts an example of data outputs which follow the data outputs of FIG. 8A, where the data outputs of the buffers in the second stage (a non-evaluation stage) differ, in accordance with various embodiments. A voltage corresponding to data 1 propagates to the output of the stage 2 buffer in the first chain 153, and to the output of the stage 1 buffer in the second chain 163. The data outputs of the buffers in the third stage are both 0 at this time so that no difference is detected and no adjustment in the power stage is performed.

FIG. 8C depicts an example of data outputs which follow the data outputs of FIG. 8B, where the data outputs of the buffers in the third stage (an evaluation stage) differ, in accordance with various embodiments. The third stage output is data 1 for the first chain and data 0 for the second chain. This indicates the propagation speed is greater in the first chain than the second chain, and that the VR output should be reduced to bring Vsense back down to Vwp. The circuit 170 then adjusts the register to achieve a desired adjustment to the power stage. The adjustment can be based on the weight of the third stage in this example.

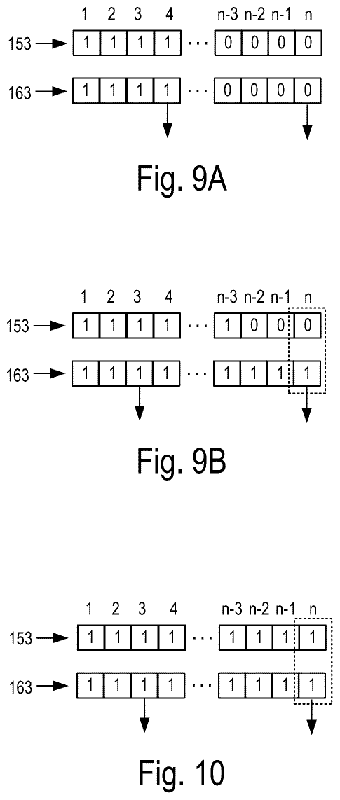

FIG. 9A depicts an example of data outputs which follow the data outputs of FIG. 8A, where the data outputs of the buffers in the third and the nth stages (evaluation stages) are the same, in accordance with various embodiments. The nth stage output is data 0 for both the first and second chains, so that no adjustment in the power stage is performed.

FIG. 9B depicts an example of data outputs which follow the data outputs of FIG. 9A, where the data outputs of the buffers in the nth stage (an evaluation stage) differ, in accordance with various embodiments. The nth stage output is data 0 for the first chain and data 1 for the second chain. This indicates the propagation speed is lower in the first chain than the second chain, and that the VR output should be increased to bring Vsense back up to Vwp. The circuit 170 then adjusts the register to achieve a desired adjustment to the power stage. Note that the adjustment is late since the outputs started to differ in the n-2^{nd} stage. In one approach, this is a tradeoff of the efficiencies achieved by using just a subset of the stages as evaluation stages.

In another approach, it is possible to obtain speed comparison data at one or more additional stages which are not used as evaluation stages. That is, the data obtained at the one or more additional stages does not trigger an adjustment in the power stage, but can be used to guide an adjustment made at a later stage. For example, the n-1st and n-2^{nd} stages can be additional stages which are used to guide an adjustment made at the nth stage. Here, since the n-1st and n-2^{nd} stage output is data 0 for the first chain and 1 for the second chain, the adjustment to the power stage that is triggered by the nth stage can take into account weights associated with the n-1st and n-2^{nd} stages, as well as the weight associated with the nth stage. The circuit 170 can take these weights into account when adjusting the power stage.

FIG. 10 depicts an example of data outputs which follow the data outputs of FIG. 8A, where the data outputs of the buffers in the nth stage (an evaluation stage) are the same, in accordance with various embodiments. The nth stage output (as well as the 1^{st} through n-1^{st} stage outputs) is data 1 for both the first and second chains, so that no adjustment in the power stage is indicated. The propagation speed is the same in both chains, indicating Vsense is essentially equal to Vwp.

In summary, FIGS. 8A-10 demonstrate that the sampling of the first and second chains of buffers can be done not after every stage, but rather at predefined evaluation stages. In such cases, the strength of the compensator response (i.e., the register shift magnitude) may be based on the number of consequent stages with different outputs.

FIGS. 8A-8C depict the case where the first, variable-delay, chain of buffers is faster than the second, reference chain. At FIG. 8C, the first chain has flipped its output at the first evaluation stage. The shift code is calculated based on the assigned weight of the stage and factoring in that there is only one pair of buffers with different output values.

In FIG. 9B, the first chain is slower than the second chain. In FIG. 9B, the second chain has flipped its output at the nth evaluation stage. The SC is calculated based on the assigned weight of the stage and optionally factoring in that there are three pairs of buffers (in the n-2^{nd} through nth stages) with different values.

In FIG. 10, the first and second chains have the same propagation speed, e.g., within a timing resolution, Teff(0). The signals in both chains reach the first and second evaluation stages together. In this case, the shift code is zero, i.e., the control register is not modified.

There is a tradeoff between the gain of the amplifiers 152a and 152b and the compensator stability. If the gain is too high, the compensator will modify the power stage resistance too frequently, which may lead to oscillations. On the other hand, a small gain increases the time-to-decision and leads to deterioration of the output signal quality.

FIG. 11 depicts a flowchart of an example process for use with the DLVR 100 of FIG. 1, in accordance with various embodiments. An operation 1100 includes resetting the buffers of first and second chains of buffers to provide a 0 output. For example, the circuit 170 can provide a reset signal to the buffers of the first and second chains of buffers. An operation 1101 includes monitoring the outputs of buffers of an evaluation stage of the first and second chains of buffers. For example, in FIG. 2, this could be the buffers 213 and 263 of the third stage S3. A decision step 1102 determines whether a speed difference is detected at the stage, e.g., whether the buffer outputs are different. If the answer to the decision step 1102 is yes, an operation 1104 includes updating the registers to thereby adjust the power stage, and the flow returns to operation 1100. If the answer to the decision step 1102 is no, a decision step 1103 determines whether there is an additional evaluation stage. If the answer to the decision step 1103 is yes, the operation 1101 is reached again to monitor the output buffers of the additional evaluation stage. For example, in FIG. 2, this could be the buffers 214 and 264 of the nth stage Sn. If the answer to the decision step 1103 is no, the flow returns to operation 1100.

The process can thus be repeated in continuous cycles of monitoring the buffers and deciding whether an adjustment is needed to the power stage.

In one approach, first and second signals propagate in the first and second chains of buffers, respectively, and the circuit 170 is configured to detect the difference in propagation speeds at multiple stages in the first and second chains of buffers and to determine a first stage of the multiple stages at which the first signal differs from the second signal. Once a stage is identified at which the propagation speeds differ, there is no need to evaluate the remaining stages. The order of evaluation of the difference in propagation speeds can start from the stage which is closest to the input ends of the VCOs and proceed toward the last stage which is furthest from the input ends.

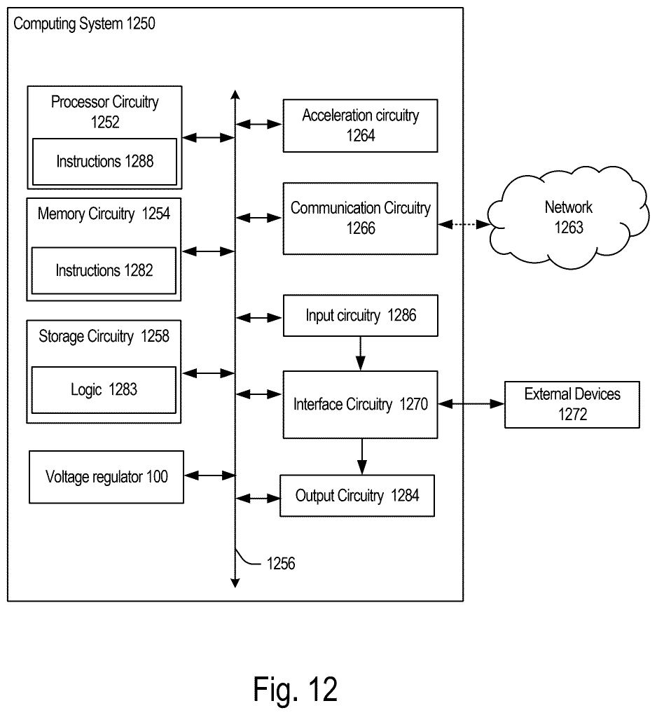

FIG. 12 illustrates an example of components that may be present in a computing system 1250 for implementing the techniques (e.g., operations, processes, methods, and methodologies) described herein.

The computing system 1250 may include any combinations of the hardware or logical components referenced herein. The components may be implemented as ICs, portions thereof, discrete electronic devices, or other modules, instruction sets, programmable logic or algorithms, hardware, hardware accelerators, software, firmware, or a combination thereof adapted in the computing system 1250, or as components otherwise incorporated within a chassis of a larger system. In an example implementation, the voltage regulator 100 of FIG. 1 is depicted. The load of the VR can be represented by one or more of the other circuitry. In one approach, all or part of the computing system 1250 is provided in a SoP, System in Package (SiP) or a System on Chip (SoC).

The voltage regulator can provide a voltage Vout to one or more of the components of the computing system 1250. Also, the computing system 1250 may contain one or more voltage regulators. The memory circuitry 1254 may store instructions and the processor circuitry 1252 may execute the instructions to perform the functions described herein.

The system 1250 includes processor circuitry in the form of one or more processors 1252. The processor circuitry 1252 includes circuitry such as, but not limited to one or more processor cores and one or more of cache memory, low drop-out voltage regulators (LDOs), interrupt controllers, serial interfaces such as SPI, I2C or universal programmable serial interface circuit, real time clock (RTC), timer-counters including interval and watchdog timers, general purpose I/O, memory card controllers such as secure digital/multi-media card (SD/MMC) or similar, interfaces, mobile industry processor interface (MIPI) interfaces and Joint Test Access Group (JTAG) test access ports. In some implementations, the processor circuitry 1252 may include one or more hardware accelerators (e.g., same or similar to acceleration circuitry 1264), which may be microprocessors, programmable processing devices (e.g., FPGA, ASIC, etc.), or the like. The one or more accelerators may include, for example, computer vision and/or deep learning accelerators. In some implementations, the processor circuitry 1252 may include on-chip memory circuitry, which may include any suitable volatile and/or non-volatile memory, such as DRAM, SRAM, EPROM, EEPROM, Flash memory, solid-state memory, and/or any other type of memory device technology, such as those discussed herein.

The processor circuitry 1252 may include, for example, one or more processor cores (CPUs), application processors, GPUs, RISC processors, Acorn RISC Machine (ARM) processors, CISC processors, one or more DSPs, one or more FPGAs, one or more PLDs, one or more ASICs, one or more baseband processors, one or more radio-frequency integrated circuits (RFIC), one or more microprocessors or controllers, a multi-core processor, a multithreaded processor, an ultra-low-voltage processor, an embedded processor, or any other known processing elements, or any suitable combination thereof. The processors (or cores) 1252 may be coupled with or may include memory/storage and may be configured to execute instructions stored in the memory/storage to enable various applications or operating systems to run on the platform 1250. The processors (or cores) 1252 is configured to operate application software to provide a specific service to a user of the platform 1250. In some embodiments, the processor(s) 1252 may be a special-purpose processor(s)/controller(s) configured (or configurable) to operate according to the various embodiments herein.

As examples, the processor(s) 1252 may include an Intel® Architecture Core™ based processor such as an i3, an i5, an i7, an i9 based processor; an Intel® microcontroller-based processor such as a Quark™, an Atom™, or other MCU-based processor; Pentium® processor(s), Xeon® processor(s), or another such processor available from Intel® Corporation, Santa Clara, California. However, any number other processors may be used, such as one or more of Advanced Micro Devices (AMD) Zen® Architecture such as Ryzen® or EPYC® processor(s), Accelerated Processing Units (APUs), MxGPUs, Epyc® processor(s), or the like; A5-A12 and/or S1-S4 processor(s) from Apple® Inc., Snapdragon™ or Centriq™ processor(s) from Qualcomm® Technologies, Inc., Texas Instruments, Inc.® Open Multimedia Applications Platform (OMAP)™ processor(s); a MIPS-based design from MIPS Technologies, Inc. such as MIPS Warrior M-class, Warrior I-class, and Warrior P-class processors; an ARM-based design licensed from ARM Holdings, Ltd., such as the ARM Cortex-A, Cortex-R, and Cortex-M family of processors; the ThunderX2® provided by Cavium™, Inc. ; or the like. In some implementations, the processor(s) 1252 may be a part of a system on a chip (SoC), System-in-Package (SiP), a multi-chip package (MCP), and/or the like, in which the processor(s) 1252 and other components are formed into a single integrated circuit, or a single package, such as the Edison™ or Galileo™ SoC boards from Intel® Corporation. Other examples of the processor(s) 1252 are mentioned elsewhere in the present disclosure.

The system 1250 may include or be coupled to acceleration circuitry 1264, which may be embodied by one or more AI/ML accelerators, a neural compute stick, neuromorphic hardware, an FPGA, an arrangement of GPUs, one or more SoCs (including programmable SoCs), one or more CPUs, one or more digital signal processors, dedicated ASICs (including programmable ASICs), PLDs such as complex (CPLDs) or high complexity PLDs (HCPLDs), and/or other forms of specialized processors or circuitry designed to accomplish one or more specialized tasks. These tasks may include AI/ML processing (e.g., including training, inferencing, and classification operations), visual data processing, network data processing, object detection, rule analysis, or the like. In FPGA-based implementations, the acceleration circuitry 1264 may comprise logic blocks or logic fabric and other interconnected resources that may be programmed (configured) to perform various functions, such as the procedures, methods, functions, etc. of the various embodiments discussed herein. In such implementations, the acceleration circuitry 1264 may also include memory cells (e.g., EPROM, EEPROM, flash memory, static memory (e.g., SRAM, anti-fuses, etc.) used to store logic blocks, logic fabric, data, etc. in LUTs and the like.

In some implementations, the processor circuitry 1252 and/or acceleration circuitry 1264 may include hardware elements specifically tailored for machine learning and/or artificial intelligence (AI) functionality. In these implementations, the processor circuitry 1252 and/or acceleration circuitry 1264 may be, or may include, an AI engine chip that can run many different kinds of AI instruction sets once loaded with the appropriate weightings and training code. Additionally or alternatively, the processor circuitry 1252 and/or acceleration circuitry 1264 may be, or may include, AI accelerator(s), which may be one or more of the aforementioned hardware accelerators designed for hardware acceleration of AI applications. As examples, these processor(s) or accelerators may be a cluster of artificial intelligence (AI) GPUs, tensor processing units (TPUs) developed by Google® Inc., Real AI Processors (RAPs™) provided by AlphaICs®, Nervana™ Neural Network Processors (NNPs) provided by Intel® Corp., Intel® Movidius™ Myriad™ X Vision Processing Unit (VPU), NVIDIA® PX™ based GPUs, the NM500 chip provided by General Vision®, Hardware 3 provided by Tesla®, Inc., an Epiphany™ based processor provided by Adapteva®, or the like. In some embodiments, the processor circuitry 1252 and/or acceleration circuitry 1264 and/or hardware accelerator circuitry may be implemented as AI accelerating co-processor(s), such as the Hexagon 685 DSP provided by Qualcomm®, the PowerVR 2NX Neural Net Accelerator (NNA) provided by Imagination Technologies Limited®, the Neural Engine core within the Apple® A11 or A12 Bionic SoC, the Neural Processing Unit (NPU) within the HiSilicon Kirin provided by Huawei®, and/or the like. In some hardware-based implementations, individual subsystems of system 1250 may be operated by the respective AI accelerating co-processor(s), AI GPUs, TPUs, or hardware accelerators (e.g., FPGAs, ASICs, DSPs, SoCs, etc.), etc., that are configured with appropriate logic blocks, bit stream(s), etc. to perform their respective functions.

The system 1250 also includes system memory 1254. Any number of memory devices may be used to provide for a given amount of system memory. As examples, the memory 1254 may be, or include, volatile memory such as random access memory (RAM), static RAM (SRAM), dynamic RAM (DRAM), synchronous DRAM (SDRAM), RAMBUS® Dynamic Random Access Memory (RDRAM®), and/or any other desired type of volatile memory device. Additionally or alternatively, the memory 1254 may be, or include, non-volatile memory such as read-only memory (ROM), erasable programmable ROM (EPROM), electrically erasable programmable (EEPROM), flash memory, non-volatile RAM, ferroelectric RAM, phase-change memory (PCM), flash memory, and/or any other desired type of non-volatile memory device. Access to the memory 1254 is controlled by a memory controller. The individual memory devices may be of any number of different package types such as single die package (SDP), dual die package (DDP) or quad die package (Q17P). Any number of other memory implementations may be used, such as dual inline memory modules (DIMMs) of different varieties including but not limited to microDIMMs or MiniDIMMs.

Storage circuitry 1258 provides persistent storage of information such as data, applications, operating systems and so forth. In an example, the storage 1258 may be implemented via a solid-state disk drive (SSDD) and/or high-speed electrically erasable memory (commonly referred to as “flash memory”). Other devices that may be used for the storage 1258 include flash memory cards, such as SD cards, microSD cards, XD picture cards, and the like, and USB flash drives. In an example, the memory device may be or may include memory devices that use chalcogenide glass, multi-threshold level NAND flash memory, NOR flash memory, single or multi-level Phase Change Memory (PCM), a resistive memory, nanowire memory, ferroelectric transistor random access memory (FeTRAM), anti-ferroelectric memory, magnetoresistive random access memory (MRAM) memory that incorporates memristor technology, phase change RAM (PRAM), resistive memory including the metal oxide base, the oxygen vacancy base and the conductive bridge Random Access Memory (CB-RAM), or spin transfer torque (STT)-MRAM, a spintronic magnetic junction memory based device, a magnetic tunneling junction (MTJ) based device, a Domain Wall (DW) and Spin Orbit Transfer (SOT) based device, a thyristor based memory device, a hard disk drive (HDD), micro HDD, of a combination thereof, and/or any other memory. The memory circuitry 1254 and/or storage circuitry 1258 may also incorporate three-dimensional (3D) cross-point (XPOINT) memories from Intel® and Micron®.

The memory circuitry 1254 and/or storage circuitry 1258 is/are configured to store computational logic 1283 in the form of software, firmware, microcode, or hardware-level instructions to implement the techniques described herein. The computational logic 1283 may be employed to store working copies and/or permanent copies of programming instructions, or data to create the programming instructions, for the operation of various components of system 1250 (e.g., drivers, libraries, application programming interfaces (APIs), etc.), an operating system of system 1250, one or more applications, and/or for carrying out the embodiments discussed herein. The computational logic 1283 may be stored or loaded into memory circuitry 1254 as instructions 1282, or data to create the instructions 1282, which are then accessed for execution by the processor circuitry 1252 to carry out the functions described herein. The processor circuitry 1252 and/or the acceleration circuitry 1264 accesses the memory circuitry 1254 and/or the storage circuitry 1258 over the interconnect (IX) 1256. The instructions 1282 direct the processor circuitry 1252 to perform a specific sequence or flow of actions, for example, as described with respect to flowchart(s) and block diagram(s) of operations and functionality depicted previously. The various elements may be implemented by assembler instructions supported by processor circuitry 1252 or high-level languages that may be compiled into instructions 1288, or data to create the instructions 1288, to be executed by the processor circuitry 1252. The permanent copy of the programming instructions may be placed into persistent storage devices of storage circuitry 1258 in the factory or in the field through, for example, a distribution medium (not shown), through a communication interface (e.g., from a distribution server (not shown)), over-the-air (OTA), or any combination thereof.

The IX 1256 couples the processor 1252 to communication circuitry 1266 for communications with other devices, such as a remote server (not shown) and the like. The communication circuitry 1266 is a hardware element, or collection of hardware elements, used to communicate over one or more networks 1263 and/or with other devices. In one example, communication circuitry 1266 is, or includes, transceiver circuitry configured to enable wireless communications using any number of frequencies and protocols such as, for example, the Institute of Electrical and Electronics Engineers (IEEE) 802.11 (and/or variants thereof), IEEE 802.23.4, Bluetooth® and/or Bluetooth® low energy (BLE), ZigBee®, LoRaWAN™ (Long Range Wide Area Network), a cellular protocol such as 3GPP LTE and/or Fifth Generation (5G)/New Radio (NR), and/or the like. Additionally or alternatively, communication circuitry 1266 is, or includes, one or more network interface controllers (NICs) to enable wired communication using, for example, an Ethernet connection, Controller Area Network (CAN), Local Interconnect Network (LIN), DeviceNet, ControlNet, Data Highway+, or PROFINET, among many others.

The IX 1256 also couples the processor 1252 to interface circuitry 1270 that is used to connect system 1250 with one or more external devices 1272. The external devices 1272 may include, for example, sensors, actuators, positioning circuitry (e.g., global navigation satellite system (GNSS)/Global Positioning System (GPS) circuitry), client devices, servers, network appliances (e.g., switches, hubs, routers, etc.), integrated photonics devices (e.g., optical neural network (ONN) integrated circuit (IC) and/or the like), and/or other like devices.

In some optional examples, various input/output (I/O) devices may be present within or connected to, the system 1250, which are referred to as input circuitry 1286 and output circuitry 1284. The input circuitry 1286 and output circuitry 1284 include one or more user interfaces designed to enable user interaction with the platform 1250 and/or peripheral component interfaces designed to enable peripheral component interaction with the platform 1250. Input circuitry 1286 may include any physical or virtual means for accepting an input including, inter alia, one or more physical or virtual buttons (e.g., a reset button), a physical keyboard, keypad, mouse, touchpad, touchscreen, microphones, scanner, headset, and/or the like. The output circuitry 1284 may be included to show information or otherwise convey information, such as sensor readings, actuator position(s), or other like information. Data and/or graphics may be displayed on one or more user interface components of the output circuitry 1284. Output circuitry 1284 may include any number and/or combinations of audio or visual display, including, inter alia, one or more simple visual outputs/indicators (e.g., binary status indicators (e.g., light emitting diodes (LEDs)) and multi-character visual outputs, or more complex outputs such as display devices or touchscreens (e.g., Liquid Crystal Displays (LCD), LED displays, quantum dot displays, projectors, etc.), with the output of characters, graphics, multimedia objects, and the like being generated or produced from the operation of the platform 1250. The output circuitry 1284 may also include speakers and/or other audio emitting devices, printer(s), and/or the like. Additionally or alternatively, sensor(s) may be used as the input circuitry 1284 (e.g., an image capture device, motion capture device, or the like) and one or more actuators may be used as the output device circuitry 1284 (e.g., an actuator to provide haptic feedback or the like). Peripheral component interfaces may include, but are not limited to, a non-volatile memory port, a USB port, an audio jack, a power supply interface, etc. In some embodiments, a display or console hardware, in the context of the present system, may be used to provide output and receive input of an edge computing system; to manage components or services of an edge computing system; identify a state of an edge computing component or service; or to conduct any other number of management or administration functions or service use cases.

The components of the system 1250 may communicate over the IX 1256. The IX 1256 may include any number of technologies, including ISA, extended ISA, I2C, SPI, point-to-point interfaces, power management bus (PMBus), PCI, PCIe, PCIx, Intel® UPI, Intel® Accelerator Link, Intel® CXL, CAPI, OpenCAPI, Intel® QPI, UPI, Intel® OPA IX, RapidIO™ system IXs, CCIX, Gen-Z Consortium IXs, a HyperTransport interconnect, NVLink provided by NVIDIA®, a Time-Trigger Protocol (TTP) system, a FlexRay system, PROFIBUS, and/or any number of other IX technologies. The IX 1256 may be a proprietary bus, for example, used in a SoC based system.

The number, capability, and/or capacity of the elements of system 1250 may vary, depending on whether computing system 1250 is used as a stationary computing device (e.g., a server computer in a data center, a workstation, a desktop computer, etc.) or a mobile computing device (e.g., a smartphone, tablet computing device, laptop computer, game console, IoT device, etc.). In various implementations, the computing device system 1250 may comprise one or more components of a data center, a desktop computer, a workstation, a laptop, a smartphone, a tablet, a digital camera, a smart appliance, a smart home hub, a network appliance, and/or any other device/system that processes data.

The techniques described herein can be performed partially or wholly by software or other instructions provided in a machine-readable storage medium (e.g., memory). The software is stored as processor-executable instructions (e.g., instructions to implement any other processes discussed herein). Instructions associated with the flowchart (and/or various embodiments) and executed to implement embodiments of the disclosed subject matter may be implemented as part of an operating system or a specific application, component, program, object, module, routine, or other sequence of instructions or organization of sequences of instructions.

The storage medium can be a tangible, non-transitory machine readable medium such as read only memory (ROM), random access memory (RAM), flash memory devices, floppy and other removable disks, magnetic storage media, optical storage media (e.g., Compact Disk Read-Only Memory (CD ROMS), Digital Versatile Disks (DVDs)), among others.

The storage medium may be included, e.g., in a communication device, a computing device, a network device, a personal digital assistant, a manufacturing tool, a mobile communication device, a cellular phone, a notebook computer, a tablet, a game console, a set top box, an embedded system, a TV (television), or a personal desktop computer.

Some non-limiting examples of various embodiments are presented below.

Example 1 includes an apparatus, comprising: a first chain of buffers disposed in respective stages, wherein respective buffers of the first chain of buffers comprise respective variable resistors; a second chain of buffers disposed in the respective stages, wherein respective buffers of the second chain of buffers comprise respective resistors; one or more amplifiers which are configured to drive the respective variable resistors of the first chain of buffers and which have inputs coupled to a sense voltage line of a load and to a work point voltage source; one or more amplifiers which are configured to drive the respective resistors of the second chain of buffers and which have inputs coupled to a same voltage source; for at least one evaluation stage of the respective stages, a comparison circuit having a first input coupled to an output node of the respective buffer in the first chain, and a second input coupled to an output node of the respective buffer in the second chain; and a circuit coupled to an output node of the comparison circuit and to a plurality of power gates.

Example 2 includes the apparatus of Example 1, wherein data of the output node of the comparison circuit is associated with whether a propagation time of a signal in the first chain of buffers is different than a propagation time of a signal in the second chain of buffers.

Example 3 includes the apparatus of Example 1 or 2, wherein the comparison circuit is among comparison circuits coupled to output nodes of respective buffers of the first and second chains in evaluation stages of the respective stages.

Example 4 includes the apparatus of Example 3, wherein: the circuit is configured to adjust a number of the power gates turned on based on data of the output node of the comparison circuit; the circuit associates weights with data from output nodes of comparison circuits in the evaluation stages in the adjusting of the number of the power gates turned on; and data from an output node of a comparison circuit of the comparison circuits which is close to input ends of the first and second chains of buffers has a greater weight than data from an output node of a comparison circuit of the comparison circuits which is further from the input ends of the first and second chains of buffers.

Example 5 includes the apparatus of any one of Examples 1-4, wherein: the respective buffers of the first chain of buffers comprise a respective first inverter which includes a first variable resistor and a respective second inverter which includes a second variable resistor; and the one or more amplifiers which are configured to drive the respective variable resistors of the first chain of buffers include a first amplifier to drive the first variable resistor of the respective first inverters and a second amplifier to drive the second variable resistor of the respective second inverters.

Example 6 includes the apparatus of Example 5, wherein: the first and second variable resistors comprise respective transistors, and the first variable resistor has an opposite polarity than the second variable resistor.

Example 7 includes the apparatus of any one of Examples 1-6, wherein: the respective buffers of the second chain of buffers comprise a respective first inverter which includes a first resistor and a respective second inverter which includes a second resistor; and the one or more amplifiers which are configured to drive the respective resistors of the second chain of buffers include an amplifier to drive the first resistor of the respective buffers of the second chain of buffers and an amplifier to drive the second resistor of the buffers of the second chain of buffers.

Example 8 includes the apparatus of any one of Examples 1-7, wherein the circuit comprises a decision logic circuit coupled to the output node of the comparison circuit, and a register coupled to the decision logic circuit.

Example 9 includes the apparatus of any one of Examples 1-8, wherein the circuit is configured to adjust a number of the power gates turned on based on data of the output node of the comparison circuit.

Example 9a includes the apparatus of any one of Examples 1-9, wherein the same voltage source is the work point voltage source.

Example 10 includes the apparatus of any one of Examples 1-9a, further comprising: a first inverter following the first chain of buffers; a first feedback path to couple to an output node of the first inverter to an input of the first chain of buffers; a second inverter following the second chain of buffers; and a second feedback path to couple to an output node of the second inverter to an input of the second chain of buffers.

Example 11 includes the apparatus of any one of Examples 1-10, wherein the apparatus is part of a digital linear voltage regulator, and the digital linear voltage regulator is provided in at least one of an integrated circuit, a System on Chip, a System in Package or a computing device.

Example 12 includes an apparatus, comprising: a power stage; a first chain of buffers configured to propagate a first signal; a second chain of buffers configured to propagate a second signal; and a circuit to detect a difference in a propagation speed of the first signal relative to a propagation speed of the second signal, and to adjust the power stage based on the difference.

Example 13 includes the apparatus of Example 12, wherein the circuit is configured to detect the difference at multiple stages in the first and second chains of buffers and to determine a first stage of the multiple stages at which the first signal differs from the second signal.

Example 14 includes the apparatus of Example 13, wherein the circuit is configured to provide an adjustment of the power stage based on a closeness of the first stage to input ends of the first and second chains of buffers.

Example 15 includes the apparatus of any one of Examples 12-14, wherein: buffers of the first chain of buffers impose respective delays on the first signal; and the respective delays are a function of a difference between a sensed voltage of the power stage and a work point voltage of the power stage.

Example 16 includes the apparatus of Example 15, wherein the buffers comprise variable resistors to impose the respective delays.

Example 17 includes a system, comprising: a first chain of buffers configured to propagate a first signal; a second chain of buffers configured to propagate a second signal; comparison circuits to detect a difference in a propagation speed of the first signal relative to a propagation speed of the second signal; circuitry coupled to the comparison circuits; a register coupled to the circuitry; and a power stage coupled to the register.

Example 18 includes the system of Example 17, wherein the circuitry is configured to update a state of the register based on outputs from the comparison circuits.

Example 19 includes the system of Example 18, wherein a number of power gates turned on in the power stage is based on the state of the register.

Example 20 includes the system of Example 18 or 19, wherein the circuitry is to reset the first and second chains of buffers in response to updating the state of the register.

Example 21 includes a method, comprising: resetting buffers of first and second chains of buffers; monitoring outputs of buffers of an evaluation stage of the first and second chains of buffers; determining whether there is a speed difference at the evaluation stage for signals propagating in the first and second chains of buffers; and if there is the speed difference, updating registers to adjust an output of a power stage.

Example 22 includes the method of Example 21, further comprising: if there is not the speed difference, monitoring outputs of buffers of another evaluation stage of the first and second chains of buffers, determining whether there is a speed difference at the another evaluation stage for the signals propagating in the first and second chains of buffers, and if there is the speed difference based on the monitoring of the another evaluation stage, updating the registers to adjust an output of a power stage.

Example 23 includes the method of Example 21 or 22, further comprising associating a weight with the updating of the registers based on a position of the evaluation stage relative to inputs of the first and second chains of buffers.

Example 24 includes the method of any one of Examples 21-23, further comprising driving variable resistors in the first chain of buffers a function of a difference between a sensed voltage of the power stage and a work point voltage of the power stage, and driving variable resistors in the second chain of buffers with a fixed bias.

Example 25 includes an apparatus, comprising means to perform Example X includes the method of any one of Examples 21-24.

Example 26 includes a machine-readable storage including machine-readable instructions which, when executed, cause a computer to implement Example X includes the method of any one of Examples 21-24.

A computer program comprising instructions which, when executed by a computer, cause the computer to carry out Example X includes the method of any one of Examples 21-24.

Various operations may be described as multiple discrete actions or operations in turn, in a manner that is most helpful in understanding the claimed subject matter. However, the order of description should not be construed as to imply that these operations are necessarily order dependent. In particular, these operations may not be performed in the order of presentation. Operations described may be performed in a different order than the described embodiment. Various additional operations may be performed and/or described operations may be omitted in additional embodiments.

The terms “substantially,” “close,” “approximately,” “near,” and “about,” generally refer to being within +/−10% of a target value. Unless otherwise specified the use of the ordinal adjectives “first,” “second,” and “third,” etc., to describe a common object, merely indicate that different instances of like objects are being referred to, and are not intended to imply that the objects so described must be in a given sequence, either temporally, spatially, in ranking or in any other manner.

For the purposes of the present disclosure, the phrases “A and/or B” and “A or B” mean (A), (B), or (A and B). For the purposes of the present disclosure, the phrase “A, B, and/or C” means (A), (B), (C), (A and B), (A and C), (B and C), or (A, B, and C).

The description may use the phrases “in an embodiment,” or “in embodiments,” which may each refer to one or more of the same or different embodiments. Furthermore, the terms “comprising,” “including,” “having,” and the like, as used with respect to embodiments of the present disclosure, are synonymous.

As used herein, the term “circuitry” may refer to, be part of, or include an Application Specific Integrated Circuit (ASIC), an electronic circuit, a processor (shared, dedicated, or group), a combinational logic circuit, and/or other suitable hardware components that provide the described functionality. As used herein, “computer-implemented method” may refer to any method executed by one or more processors, a computer system having one or more processors, a mobile device such as a smartphone (which may include one or more processors), a tablet, a laptop computer, a set-top box, a gaming console, and so forth.

The terms “coupled,” “communicatively coupled,” along with derivatives thereof are used herein. The term “coupled” may mean two or more elements are in direct physical or electrical contact with one another, may mean that two or more elements indirectly contact each other but still cooperate or interact with each other, and/or may mean that one or more other elements are coupled or connected between the elements that are said to be coupled with each other. The term “directly coupled” may mean that two or more elements are in direct contact with one another. The term “communicatively coupled” may mean that two or more elements may be in contact with one another by a means of communication including through a wire or other interconnect connection, through a wireless communication channel or link, and/or the like.

Reference in the specification to “an embodiment,” “one embodiment,” “some embodiments,” or “other embodiments” means that a particular feature, structure, or characteristic described in connection with the embodiments is included in at least some embodiments, but not necessarily all embodiments. The various appearances of “an embodiment,” “one embodiment,” or “some embodiments” are not necessarily all referring to the same embodiments. If the specification states a component, feature, structure, or characteristic “may,” “might,” or “could” be included, that particular component, feature, structure, or characteristic is not required to be included. If the specification or claim refers to “a” or “an” element, that does not mean there is only one of the elements. If the specification or claims refer to “an additional” element, that does not preclude there being more than one of the additional elements.

Furthermore, the particular features, structures, functions, or characteristics may be combined in any suitable manner in one or more embodiments. For example, a first embodiment may be combined with a second embodiment anywhere the particular features, structures, functions, or characteristics associated with the two embodiments are not mutually exclusive.

While the disclosure has been described in conjunction with specific embodiments thereof, many alternatives, modifications and variations of such embodiments will be apparent to those of ordinary skill in the art in light of the foregoing description. The embodiments of the disclosure are intended to embrace all such alternatives, modifications, and variations as to fall within the broad scope of the appended claims.

In addition, well-known power/ground connections to integrated circuit (IC) chips and other components may or may not be shown within the presented figures, for simplicity of illustration and discussion, and so as not to obscure the disclosure. Further, arrangements may be shown in block diagram form in order to avoid obscuring the disclosure, and also in view of the fact that specifics with respect to implementation of such block diagram arrangements are highly dependent upon the platform within which the present disclosure is to be implemented (i.e., such specifics should be well within purview of one skilled in the art). Where specific details (e.g., circuits) are set forth in order to describe example embodiments of the disclosure, it should be apparent to one skilled in the art that the disclosure can be practiced without, or with variation of, these specific details. The description is thus to be regarded as illustrative instead of limiting.

An abstract is provided that will allow the reader to ascertain the nature and gist of the technical disclosure. The abstract is submitted with the understanding that it will not be used to limit the scope or meaning of the claims. The following claims are hereby incorporated into the detailed description, with each claim standing on its own as a separate embodiment.

What is claimed is:

1. An apparatus, comprising:
a first chain of buffers disposed in respective stages, wherein respective buffers of the first chain of buffers comprise respective variable resistors;
a second chain of buffers disposed in the respective stages, wherein respective buffers of the second chain of buffers comprise respective resistors;
one or more amplifiers which are configured to drive the respective variable resistors of the first chain of buffers and which have inputs coupled to a sense voltage line of a load and to a work point voltage source;
one or more amplifiers which are configured to drive the respective resistors of the second chain of buffers and which have inputs coupled to a same voltage source;
for at least one evaluation stage of the respective stages, a comparison circuit having a first input coupled to an output node of the respective buffer in the first chain, and a second input coupled to an output node of the respective buffer in the second chain; and
a circuit coupled to an output node of the comparison circuit and to a plurality of power gates.

2. The apparatus of claim 1, wherein data of the output node of the comparison circuit is associated with whether a propagation time of a signal in the first chain of buffers is different than a propagation time of a signal in the second chain of buffers.

3. The apparatus of claim 1, wherein the comparison circuit is among comparison circuits coupled to output nodes of respective buffers of the first and second chains in evaluation stages of the respective stages.

4. The apparatus of claim 3, wherein:
the circuit is configured to adjust a number of the power gates turned on based on data of the output node of the comparison circuit;
the circuit associates weights with data from output nodes of comparison circuits in the evaluation stages in the adjusting of the number of the power gates turned on; and
data from an output node of a comparison circuit of the comparison circuits which is close to input ends of the first and second chains of buffers has a greater weight than data from an output node of a comparison circuit of the comparison circuits which is further from the input ends of the first and second chains of buffers.

5. The apparatus of claim 1, wherein:
the respective buffers of the first chain of buffers comprise a respective first inverter which includes a first variable resistor and a respective second inverter which includes a second variable resistor; and
the one or more amplifiers which are configured to drive the respective variable resistors of the first chain of buffers include a first amplifier to drive the first variable resistor of the respective first inverters and a second amplifier to drive the second variable resistor of the respective second inverters.

6. The apparatus of claim 5, wherein:
the first and second variable resistors comprise respective transistors, and
the first variable resistor has an opposite polarity than the second variable resistor.

7. The apparatus of claim 1, wherein:
the respective buffers of the second chain of buffers comprise a respective first inverter which includes a first resistor and a respective second inverter which includes a second resistor; and
the one or more amplifiers which are configured to drive the respective resistors of the second chain of buffers include an amplifier to drive the first resistor of the respective buffers of the second chain of buffers and an amplifier to drive the second resistor of the buffers of the second chain of buffers.

8. The apparatus of claim 1, wherein the circuit comprises a decision logic circuit coupled to the output node of the comparison circuit, and a register coupled to the decision logic circuit.

9. The apparatus of claim 1, wherein the circuit is configured to adjust a number of the power gates turned on based on data of the output node of the comparison circuit.

10. The apparatus of claim 1, further comprising:
a first inverter following the first chain of buffers;
a first feedback path to couple to an output node of the first inverter to an input of the first chain of buffers;
a second inverter following the second chain of buffers; and
a second feedback path to couple to an output node of the second inverter to an input of the second chain of buffers.

11. The apparatus of claim 1, wherein the apparatus is part of a digital linear voltage regulator, and the digital linear voltage regulator is provided in at least one of an integrated circuit, a System on Chip, a System in Package or a computing device.

12. An apparatus, comprising:
a power stage;
a first chain of buffers configured to propagate a first signal;
a second chain of buffers configured to propagate a second signal; and
a circuit to detect a difference in a propagation speed of the first signal relative to a propagation speed of the second signal, and to adjust the power stage based on the difference.

13. The apparatus of claim 12, wherein the circuit is configured to detect the difference at multiple stages in the first and second chains of buffers and to determine a first stage of the multiple stages at which the first signal differs from the second signal.

14. The apparatus of claim 13, wherein the circuit is configured to provide an adjustment of the power stage based on a closeness of the first stage to input ends of the first and second chains of buffers.

15. The apparatus of claim 12, wherein:
buffers of the first chain of buffers impose respective delays on the first signal; and
the respective delays are a function of a difference between a sensed voltage of the power stage and a work point voltage of the power stage.

16. The apparatus of claim 15, wherein the buffers comprise variable resistors to impose the respective delays.

17. A system, comprising:
a first chain of buffers configured to propagate a first signal;
a second chain of buffers configured to propagate a second signal;
comparison circuits to detect a difference in a propagation speed of the first signal relative to a propagation speed of the second signal;
circuitry coupled to the comparison circuits;
a register coupled to the circuitry; and
a power stage coupled to the register.

18. The system of claim 17, wherein the circuitry is configured to update a state of the register based on outputs from the comparison circuits.

19. The system of claim 18, wherein a number of power gates turned on in the power stage is based on the state of the register.

20. The system of claim 18, wherein the circuitry is to reset the first and second chains of buffers in response to updating the state of the register.
